(19) United States
(12) Patent Application Publication
(10) Pub. No.: US 2007/0139119 A1
(43) Pub. Date: Jun. 21, 2007

(54) Variable attenuator

(76) Inventor: Iwao Kojima, Kyoto (JP)

Correspondence Address: RATNERPRESTIA, P.O. BOX 980, VALLEY FORGE, PA, 19482, US

(21) Appl. No.: 10/583,898

(22) PCT Filed: Dec. 7, 2004
(86) PCT No.: PCT/JP04/18223

§ 371 Date: Jun. 21, 2006

(30) Foreign Application Priority Data
Dec. 25, 2003 (JP) 2003-430738

(51) Int. Cl. H03G 3/00

(52) U.S. Cl. 330/284

(57) ABSTRACT

A variable attenuator which can sequentially control attenuation effectively and has a small variation in manufacturing, is provided. The variable attenuator has a first signal input terminal; a first signal output terminal; a first control terminal receiving a control voltage; an analog/digital converter converting the control voltage to M (M is a positive integer of 2 or more) control signals; and N (N is a positive integer satisfying N≧M) variable impedance elements which are connected in parallel and/or in series between the first signal input terminal and the first signal output terminal, and each impedance of which is varied by either one of the control signals.

### TECHNICAL FIELD

The present invention relates to a sequential variable attenuator using a MOS transistor.

### BACKGROUND ART

Recently, a high-frequency transistor made of a material such as Si or SiGe has been increasingly developed and high integration and high functioning have been implemented. Thus, a power amplifier, a drive amplifier for the power amplifier, a low noise amplifier or the like needs to control sequentially amplification or an incorporate sequential variable attenuator. Although a variable attenuator using a MOS transistor has been proposed conventionally to implement the above function, it can only implement discrete control or even when sequential variation can be implemented, its variation in manufacturing is large.

The conventional variable attenuator using the MOS transistor will be described in detail with reference to FIG. 11. FIG. 11 is a diagram showing the conventional variable attenuator using the MOS transistor.

The conventional variable attenuator includes a signal input terminal 1, a signal output terminal 2, capacitors 705 and 709, resistors 715, 716, 717, 718, 719 and 720, control terminals 721 and 722, and N-type MOS transistors 723, 724 and 725.

A signal inputted via the signal input terminal 1 is outputted to the N-type MOS transistor 725 through the decoupling capacitor 705 and outputted from the signal output terminal 2 through the decoupling capacitor 709.

When a voltage (High-level voltage) which turns ON the N-type MOS transistor 725 is applied to the control terminal 721 in the variable attenuator, the N-type MOS transistor 725 is turned ON. When a voltage (Low-level voltage) which turns OFF the N-type MOS transistors 723 and 724 is applied to the control terminal 722 in the variable attenuator, the N-type MOS transistors 723 and 724 connected on a signal line in parallel are turned OFF.

In this state, the signal inputted via the signal input terminal 1 can be outputted from the signal output terminal 2 through the N-type MOS transistor 725 with minute attenuation.

Meanwhile, when a voltage (Low-level voltage) which turns OFF the N-type MOS transistor 725 is applied to the control terminal 721, the N-type MOS transistor 725 is turned OFF, and when a voltage (High-level voltage) which turns ON the N-type MOS transistors 723 and 724 is applied to the control terminal 722, the N-type MOS transistors 723 and 724 are turned ON.

In this state, the input voltage inputted via the signal input terminal 1 is attenuated by the resistor 716 having a small resistance value and divided by the resistors 720 and 718, so that largely attenuated signal is outputted from the signal output terminal 2.
Patent document1: JP-A-6-224691
Patent document2: JP-A-2001-68967

### DISCLOSURE OF THE INVENTION

Problems to be Solved by the Invention

The conventional variable attenuator has a problem that only discrete control of attenuation in two stages is basically implemented. Although the attenuation can be sequentially controlled by sequentially varying a voltage applied to the control terminals 721 and 722, in this case, the variation in attenuation with respect to the voltage applied to the control terminals 721 and 722 becomes very steep in the vicinity of a threshold voltage VT of the MOS transistors 723, 724 and 725. Thus, the conventional variable attenuator is very likely to be affected by the manufacturing variation of the threshold voltage VT.

The present invention was made in view of the above problems and it is an object of the present invention to provide a variable attenuation attenuator (referred to as the variable attenuator hereinafter) which can easily vary attenuation in multistage.

It is another object of the present invention to provide a variable attenuator which can vary attenuation in a wide range which is to be increased effectively by increasing the number of stages so as to correspond to the number of stages.

It is still another object of the present invention to provide a high-precision variable attenuator having a small manufacturing variation.

It is still another object of the present invention to provide a variable attenuator which has a relation between a control voltage and an attenuation GL expressed in logarithm (dB) can be approximately expressed linearly, and which can be easily used in an electronic device.

Means for Solving the Problems

In order to solve the above problem, the present invention provides the following configuration.

A variable attenuator according to a first aspect of the present invention has a first signal input terminal; a first signal output terminal; a first control terminal receiving a control voltage; an analog/digital converter converting the control voltage to M (M is a positive integer of 2 or more) control signals; and N (N is a positive integer satisfying N≧M) variable impedance elements which are connected in parallel and/or in series between the first signal input terminal and the first signal output terminal and each impedance of which is varied by either one of the control signals.

The variable attenuator according to this invention generates a plurality of control signals from a control voltage and controls the plurality of variable impedance elements by a plurality of control signals. In this configuration, the attenuation can be easily varied in multistage. By increasing the number of stages, the attenuation can be sequentially varied effectively. This invention realizes the high-precision variable attenuator having a small manufacturing variation.

In the variable attenuator according to another aspect of the present invention, the N variable impedance elements have the same configuration and they are connected in parallel between the first signal input terminal and the first signal output terminal.

The present invention realizes the variable attenuator in which the control voltage and the attenuation have a predetermined relation, so that it can be easily applied to an electronic device.

In the variable attenuator according to still another aspect of the present invention, the control signals are binary digital signals having a first value and a second value, and the analog/digital converter outputs K (K is an integer satisfying 0≦K≦M) control signals having the first value and (M−K) control signals having the second value, a number of K is almost in proportion to a level of the control voltage, and N and M are the same value, and the N variable impedance elements have the same configuration and are connected in parallel between the first signal input terminal and the first signal output terminal and switched to have either one of two impedance values by the respective control signals.

This invention realizes the variable attenuator in which the control voltage and the attenuation have a predetermined relation (the control voltage and the attenuation GL expressed in logarithm (dB) can be expressed approximately linearly, for example), so that it can be easily applied to an electronic device.

In the variable attenuator according to still another aspect of the present invention, the variable impedance element has a second signal input terminal; a second signal output terminal; a second control terminal receiving the control signal; a constant voltage terminal; a series connector having two resistors which are connected in series, have almost the same impedance, and are inserted between the second signal input terminal and the second signal output terminal; and a switching element which are inserted between a connecting point of the two resistors and the constant voltage terminal and are turned on or off by the control signal.

This invention realizes the variable attenuator which has a relation in which a control voltage and an attenuation GL expressed in logarithm (dB) can be expressed approximately linearly by setting an output impedance and an input impedance of a circuit connected to the input side and the output side of the variable attenuator to a value which satisfies a predetermined matching condition, so that it can be easily used in the electronic device. The term “constant voltage terminal” is a terminal of a constant potential, which is a ground terminal typically.

In the variable attenuator according to still another aspect of the present invention, the variable impedance element has a second signal input terminal; a second signal output terminal; a second control terminal receiving a control signal; a constant voltage terminal; a series connector having first and second passive elements connected in series and being inserted between the second signal input terminal and the second signal output terminal; and a first MOS transistor which has a drain connected to a connecting point between the first and second passive elements, a source connected to the constant voltage terminal directly or through a resistor, and a gate receiving the control signal.

According to the present invention, the output impedance and the input impedance of the circuit connected to the input side and the output side of the variable attenuator are set to the value which satisfies the predetermined matching condition. Thus, the present invention realizes the variable attenuator which has a relation in which the control voltage and the attenuation GL expressed in logarithm (dB) can be expressed approximately linearly, so that the variable attenuator can be easily used in the electronic device.

In the variable attenuator according to still another aspect of the present invention, the first and second passive elements are resistors.

The variable attenuator according to still another aspect of the present invention further has a third signal input terminal and a third signal output terminal, in which each variable impedance element further has a second circuit which is the same circuit as a first circuit connected between the first signal input terminal and the first signal output terminal in parallel or in series, and impedance of which is varied by the same control signal, and the second circuits of the N variable impedance elements are connected in parallel or in series between the third signal input terminal and the third signal output terminal.

The present invention realizes the variable attenuator which receives two signals and attenuates them with the same attenuation and outputs them. The present invention realizes the variable attenuator which is suitable for attenuating a balanced signal pair (differential signal pair) or a complemented signal pair. Since the balanced signal pair or the complemented signal pair is inputted to the variable attenuator according to the present invention, the variable attenuator can be prevented from being affected by external disturbance.

In the variable attenuator according to still another aspect of the present invention, the variable impedance element has a second signal input terminal; a second signal output terminal; a fourth signal input terminal; a fourth signal output terminal; a second control terminal receiving the control signal; a constant voltage terminal; a first series connector having first and second passive elements which are connected in series and inserted between the second signal input terminal and the second signal output terminal; a second series connector having third and fourth passive elements which are connected in series and inserted between the fourth signal input terminal and the fourth signal output terminal; a first MOS transistor which has a drain connected to a connecting point between the first and second passive elements, a source connected to the constant voltage terminal directly or through a fifth passive element and a gate receiving the control signal; and a second MOS transistor which has a drain connected to a connecting point between the third and fourth passive elements, a source connected to the constant voltage terminal directly or through the fifth passive element, or through a sixth passive element having the same impedance as that of the fifth passive element and a gate receiving the control signal.

According to the present invention, the output impedance and the input impedance of the circuit connected to the input side and the output side of the variable attenuator are set to the value which satisfies the predetermined matching condition. Thus, the present invention realizes the variable attenuator which receives two signals, attenuates them with the same attenuation to output them, and has a relation in which the control voltage and the attenuation GL expressed in logarithm (dB) can be expressed approximately linearly, so that it can be easily used in the electronic device.

In the variable attenuator according to still another aspect of the present invention, the first, second, third, and fourth passive elements are resistors, or those passive elements and the fifth passive element are resistors, or those passive elements and the fifth and sixth passive elements are resistors.

While the novel features of the invention are set forth particularly in the appended claims, the invention, both as to organization and content, will be better understood and appreciated, along with other objects and features thereof, from the following detailed description taken in conjunction with the drawings.

Effects of the Invention

According to the present invention, the variable attenuator which can easily vary the attenuation in many stages can be realized.

According to the present invention, the variable attenuator which can sequentially vary the attenuation effectively by increasing the number of stages can be realized.

According to the present invention, the high-precision variable attenuator having the small manufacturing variation can be realized.

According to the present invention, there can be provided an effect that the variable attenuator which has the relation in which the control voltage and the attenuation GL expressed in logarithm (dB) can be expressed approximately linearly by setting the output impedance and the input impedance of the circuit connected to the input side and the output side of the variable attenuator to the value which satisfies the predetermined matching condition, and which can be easily applied to an electronic device, can be realized.

According to the present invention, the variable attenuator which has the pair of signal input terminals receiving the balanced signal pair (differential signal pair) or the complementary signal pair and the pair of signal output terminals and can be prevented from being affected by external disturbance can be realized.

### BRIEF DESCRIPTION OF DRAWINGS

FIG. 1 is a diagram showing a variable attenuator according to a first embodiment of the present invention;

FIG. 2 is a diagram showing a variable impedance element according to the first embodiment in detail;

FIG. 3 is a diagram showing a voltage comparator according to the first embodiment in detail;

FIG. 4 is a diagram showing a reference voltage source according to the first embodiment in detail;

FIGS. 5 are diagrams showing an operation principle of the variable attenuator according to the first embodiment;

FIG. 6 is a diagram showing an equivalent circuit of the variable attenuator according to embodiment 1;

FIGS. 7 are diagrams showing a simulation result using a circuit according to the first embodiment;

FIG. 8 is a diagram showing a differential variable attenuator according to a second embodiment of the present invention;

FIG. 9 is a diagram showing a variable impedance element according to the second embodiment in detail;

FIG. 10 is a block diagram showing a configuration of an analog/digital converter according to a third embodiment; and

FIG. 11 is a diagram showing a conventional variable attenuator.

### DESCRIPTION OF THE REFERENCE NUMERALS

1, 211, 2111, 2112 signal input terminal
2, 212, 2121, 2122 signal output terminal
3, 213 control terminal
21, 81 variable impedance element
31 voltage comparator
41 reference voltage source
214, 215, 217, 411, 2141, 2151, 2142, 2152, 3113, 3114, 3116, 3117, 3120 resistor
216, 2161, 2162 N-type MOS transistor
311, 312 input terminal
313, 401 output terminal
410, 3115 current source
3111, 3112 NPN transistor
3118, 3119 PNP bipolar transistor
3121 capacitor
1001 input buffer
1002 subtracter
1003 voltage comparator
1004 logic control unit
1005 D/A converter
1006 output register
1007 control signal generation unit
1008 control signal output terminal
   Best Mode for Carrying Out The Invention

An embodiment for the best mode for carrying out the present invention will be described below in details with reference to the drawings.

It will be recognized that some or all of the drawings are schematic representations for purposes of illustration and do not necessarily depict the actual relative sizes or locations of the elements shown.

### EMBODIMENT 1

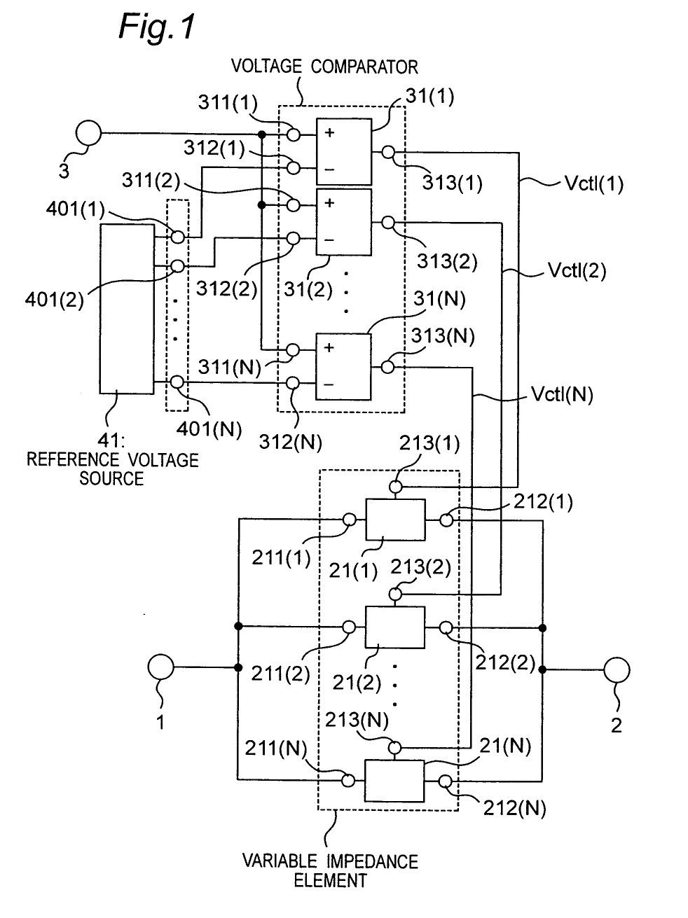

A variable attenuator according to a first embodiment of the present invention will be described with reference to FIGS. 1 to 7. FIG. 1 is a circuit diagram showing the variable attenuator according to the first embodiment of the present invention.

The variable attenuator has a signal input terminal 1 receiving a signal of which attenuation is to be controlled, a signal output terminal 2 outputting an attenuated signal, a control terminal 3 receiving a control voltage from the outside, N (positive integer satisfying N≧2) variable impedance elements 21(1) to 21(N), N voltage comparators 31(1) to 31(N), and a reference voltage source 41.

The N voltage comparators 31(i) (1≦i≦N) have the same circuit configuration and the same circuit constant. The N voltage comparators 31(1) to 31(N) and the reference voltage source 41 constitute an analog/digital converter which converts the control voltage inputted via the control terminal 3, to N control signals Vctl(i) (1≦i≦N). The control signal Vctl(i) (1≦i≦N) is a binary digital signal.

The analog/digital converter (voltage comparators 31(1) to 31(N) and the reference voltage source 41) outputs K (K is an integer satisfying 0≦K≦N) control signals having a first value (Low level in the first embodiment) of which number (K) is almost proportional to a level of the control voltage, and (N−K) control signals having a second value (High level in the first embodiment).

The variable impedance elements 21(1) to 21(N) have the same circuit configuration and the same circuit constant, and they are connected in parallel between the signal input terminal 1 and the signal output terminal 2. The variable impedance element 21(i) (1≦i≦N) receives the control signal Vctl(i) (1≦≦N), respectively and switched to either of two impedance values.

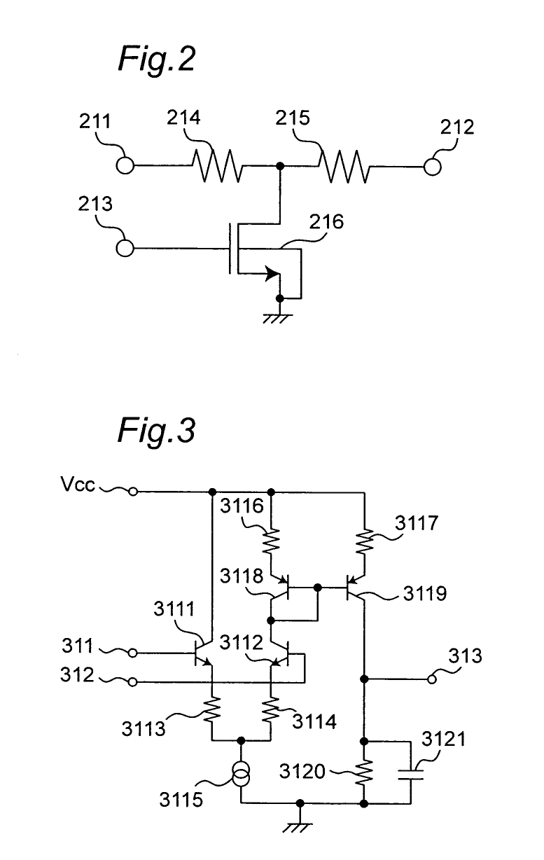

FIG. 2 is a diagram showing a configuration of the variable impedance element in detail. The variable impedance element 21(i) (1≦i≦N) has an signal input terminal 211, a signal output terminal 212, a control terminal 213 receiving the control signal, resistors 214 and 215, and an N-type MOS transistor 216.

The resistors 214 and 215 constitute a series connector and connected between the signal input terminal 211 and the signal output terminal 212. A resistance value R214 of the resistor 214 and a resistance value R215 of the resistor 215 are the same value R.

The N-type MOS transistor 216 is a switching element having a drain connected to a connecting point between the resistor 214 and the resistor 215 and a grounded source and a gate to which the control signal Vct1(i) (1≦i≦N) is inputted to be turned on or off.

The signal input terminal 211(i) (1≦i≦N) of the variable impedance element 21(i) (1≦i≦N) is connected to the signal input terminal 1. The signal output terminal 212(i) (1≦i≦N) of the variable impedance element 21(i) (1≦i≦N) is connected to the signal output terminal 2.

The control terminal 213(i) (1≦i≦N) of the variable impedance element 21(i) (1≦i≦N) is connected to the output terminal 313(i) (1≦i≦N) of the voltage comparator 31(i) (1≦i≦N), respectively.

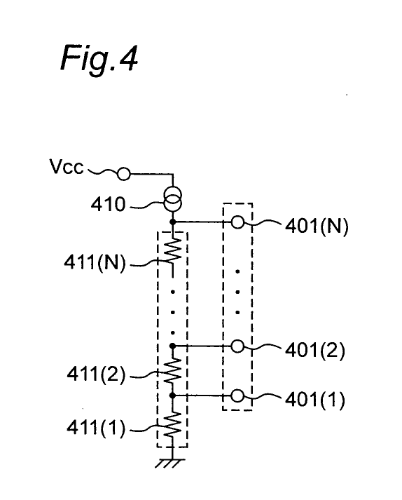

Next, the analog/digital converter will be described. FIG. 4 is a diagram showing a configuration of the reference voltage source. The reference voltage source 41 has N output terminals 401(i) (1≦i≦N) of which number is the same as the number of the variable impedance elements, and N resistors 411(i) (1≦i≦N) connected in series, and one current source 410.

The N resistors 411(i) (1≦i≦N) have the same resistance value R411. The current source 410 applies a constant current I to the N resistors 411(i) (1≦i≦N). Each connection point between the current source 410 and the N resistor 411(i) (1≦i≦N) is connected to the output terminal 401(i) (1≦i≦N) to output the reference voltage Vref(i)=i×R411×I (1≦i≦N). The reference voltage source 41 may have any configuration operable to supply a fixed voltage other than that shown in FIG. 4.

FIG. 3 is a view showing a configuration of the voltage comparator. The voltage comparator 31(i) (1≦i≦N) has input terminals 311 and 312, an output terminal 313, NPN transistors 3111 and 3112, PNP bipolar transistors 3118 and 3119, resistors 3113, 3114, 3116, 3117, and 3120, a capacitor 3121, and a current source 3115.

Here, N-type MOS transistors may be used instead of the NPN transistors 3111 and 3112, and P-type MOS transistors may be used instead of the PNP transistors 3118 and 3119.

The input terminal 311(i) of the voltage comparator 31(i) (1≦i≦N) is connected to the control terminal 3 to receive a control voltage from the outside. The input terminal 312(i) of the voltage comparator 31(i) (1≦i≦N) is connected to the output terminal 401(i) (1≦i≦N) of the reference voltage source 41, respectively, to receive the reference voltage Vref(i)=i×R411×I.

The voltage comparator 31(i) (1≦i≦N) compares the control voltage from the outside with the reference voltage Vref(i). When the control voltage is higher than the reference voltage Vref(i), the voltage comparator 31(i) outputs a Low level. Meanwhile, when the control voltage is lower than the reference voltage Vref(i), the voltage comparator 31(i) outputs a High level.

That is, K (K is an integer satisfying 0≦K≦N) voltage comparators 31(1) to 31(K) of which number (K) is almost proportional to the level of the control voltage output the control signals having a first value (Low level in the first embodiment) and the (N−K) voltage comparators 31(K+1) to 31(N) output control signals having a second value (High level in the first embodiment).

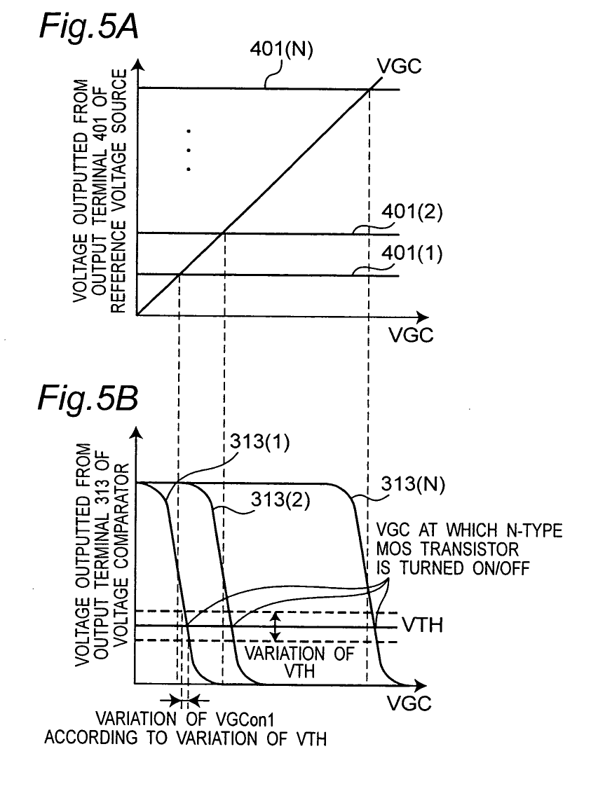

An operation principle of the variable attenuator will be described with reference to FIG. 5.

In FIG. 5A, a horizontal axis shows the control voltage VGC to be inputted to the control terminal 3, and a vertical axis shows the reference voltage Vref(i)=i×R411×I to be outputted from the output terminal 401(i) (1≦i≦N) of the reference voltage source 41.

In FIG. 5B, a horizontal axis shows the control voltage VGC to be inputted to the control terminal 3, and a vertical axis shows the voltage of the output terminal 313 (i) of the voltage comparator 31(i) (1≦i≦N) which receives the control voltage VGC. The control signal outputted from the output terminal 313(i) of the voltage comparator 31(i) (1≦i≦N) is a binary value having the High level and the Low level which are varied at the center of the voltage when the control voltage VGC is equivalent to the voltage of the output terminal 401(i) of the reference voltage source 41.

The output terminal 313(i) (1≦i≦N) of the voltage comparator is connected to the control terminal 213(i) of the variable impedance element 21.

When the voltage of the output terminal 313(i) (1≦i≦N) of the voltage comparator 31 becomes High level and it becomes higher than a threshold voltage VTH which turns ON the N-type MOS transistor 216(i) of the variable impedance element 21(i), the N-type MOS transistor 216(i) of the variable impedance element 21(i) is turned ON.

When the voltage of the output terminal 313(i) (1≦i≦N) of the voltage comparator 31 becomes Low level and it becomes lower than the threshold voltage VTH, the N-type MOS transistor 216(i) is turned OFF.

That is, when the control voltage VGC is not more than the voltage of the output terminal 401(i) (1≦i≦N) of the reference voltage source 41, the N-type MOS transistor 216(i) of the variable impedance element 21(i) (1≦i≦N) is turned OFF and when the control voltage VGC is more than the voltage of the output terminal 401(i) of the reference voltage source 41, it is turned ON.

It is assumed that the control voltage VGC at a point when the N-type MOS transistor 216 is changed from ON state to OFF state is VGCon1. A variation of the control voltage VGConl is determined by a variation of the threshold voltage VTH of the N-type MOS transistor 216 mainly as shown in FIG. 5B.

As can be seen from FIG. 5B, the more the voltage of the output terminal 313(i) (1≦i≦N) of the voltage comparator 31 is varied (the steeper the voltage drop is), the less the control voltage VGCon1 caused by the variation of the threshold voltage VTH is varied, and the less the voltage is varied, the more the control voltage VGCon1 caused by the variation of the threshold voltage VTH is varied.

That is, when the control voltage VGC to be inputted via the control terminal 3 is in a sufficiently low state, all of the N-type MOS transistors 216 of the variable impedance elements 21(i) (1≦i≦N) are in ON state.

As the control voltage VGC is gradually increased, when it reaches around a voltage value of the output terminal 401(1) of the reference voltage source 41, the N-type MOS transistor 216(1) of the variable impedance element 21(1) is turned off.

As the control voltage VGC is further increased, when it reaches around a voltage value of the output terminal 401(2) of the reference voltage source 41, the N-type MOS transistor 216(2) of the variable impedance element 21(2) is also turned off.

Similarly, as the control voltage VGC is further raised, the N-type MOS transistors of the variable impedance elements are turned OFF sequentially.

When the control voltage VGC inputted to the control terminal 3 is sufficiently raised, all of the N-type MOS transistors of the variable impedance elements 21(i) (1≦i≦N) are turned OFF.

Here, it is assumed that n (0≦n≦N) N-type MOS transistors 216 of the variable impedance elements are turned ON and (N−n) N-type MOS transistors 216 of the variable impedance element are turned OFF at a certain control voltage VGC.

Then, a signal attenuation GL in a case where a signal source having an output impedance Rs is connected to the signal input terminal 1, and a load having an impedance RL is connected to the signal output terminal 2 is to be considered.

For the sake of simplification, it is assumed that an ON resistance Ron when the N-type MOS transistor 216 of the variable impedance element is turned ON is much smaller than resistance values R214 and R215 of the resistors 214 and 215 of the variable impedance element.

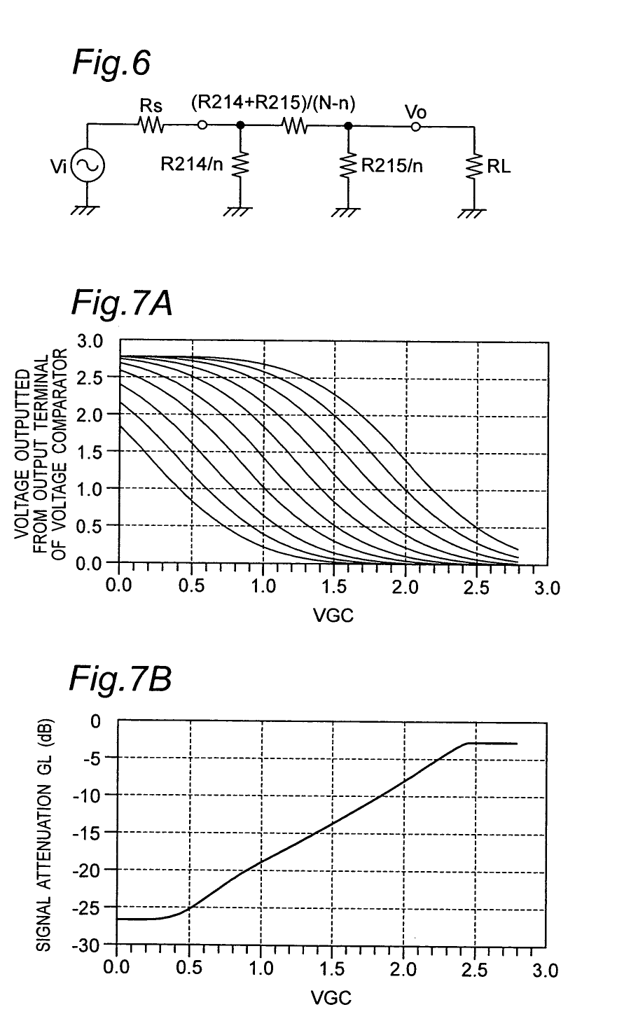

An equivalent circuit is shown in FIG. 6 and thus the signal attenuation GL is obtained in accordance with the following equation.

$$GL = \frac{\frac{RL \cdot R 215 / n}{RL + R 215 / n}}{\frac{Rs \cdot R 214 / n}{Rs + R 214 / n} + \frac{R 214 + R 215}{N - n} + \frac{RL \cdot R 215 / n}{RL + R 215 / n}} \cdot \frac{R 214 / n}{Rs + R 214 / n} \qquad [ Equation 1 ]$$

FIG. 7 shows Sim(simulation) results when Rs=50Ω, R214=100Ω, R215=100Ω, RL=50Ωand N=10 . In FIG. 7A, a horizontal axis shows the control voltage VGC inputted to the control terminal 3, and a vertical axis shows the voltage of the output terminal 313(i) of the voltage comparator 31(i) (1≦i≦N). In FIG. 7B, a horizontal axis shows the control voltage VGC, and a vertical axis shows the signal attenuation GL expressed in logarithm (dB).

As shown in FIG. 7B, the control voltage and the signal attenuation GL expressed in logarithm (dB) have a relation in which they can be approximately expressed as a linear equation by setting the output impedance Rs and the input impedance RL of the circuits connected to the input side and the output side of the variable attenuator, respectively to a value which satisfies a predetermined matching condition. The signal attenuation GL expressed in logarithm (dB) is varied effectively sequentially and linearly according to the control voltage.

According to the first embodiment, the resistors R214 and R215 have the same resistance value R. A matching impedance of the output impedance Rs of the input side of the variable attenuator and the input impedance RL of the output side of the variable attenuator is such that Rs=RL =R/2.

As described above, it is preferable that the variation in voltage of the output terminal 313(i) of the voltage comparator 31(i) (1≦i≦N) to the control voltage VGC is large because the variation of the control voltage VGConl caused by the variation of the threshold voltage VTH of the N-type MOS transistor can be small.

However, when the voltage variation is too large, the signal attenuation GL is discretely varied in the vicinity of the point in which the voltage of the output terminal 313(i) of the voltage comparator 31(i) (1≦i≦N) is varied, which loses continuity of the variation of the signal attenuation GL.

The control voltage VGCon1 can be prevented from being affected by the variation of the threshold voltage VTH while the continuity of the variation of the signal attenuation GL is maintained by increasing the number N of the variable impedance elements, the voltage comparators, and the output terminals of the reference voltage source.

The variation in voltage of the output terminal 313 (i) of the voltage comparator 31 can be appropriately set by appropriately setting the resistance values of the inner resistors 3113, 3114, 3116 and 3117 of the voltage comparator 31.

Since the N variable impedance elements 21(i) (1≦i≦N) having the same circuit and the N voltage comparators 31(i) (1≦i≦N) having the same circuit are provided, the variation in manufacturing can be made small.

In addition, the voltage comparator 31 may transmit control signal of N-bit (N is a positive integer of 2 or more) binary data to the variable impedance element 21 corresponding to each binary bit. According to the first embodiment, the resistance value of the variable impedance element corresponding to the LSB is set such that R214=R215=R, and the resistance value of the variable impedance element corresponding to its upper place bit is set such that R214=R215=R/2, and the resistance value of the j-th variable impedance element 21(j) from the LSB is set such that R214=R215=R/2^{(j-1)}(1≦j≦N).

### EMBODIMENT 2

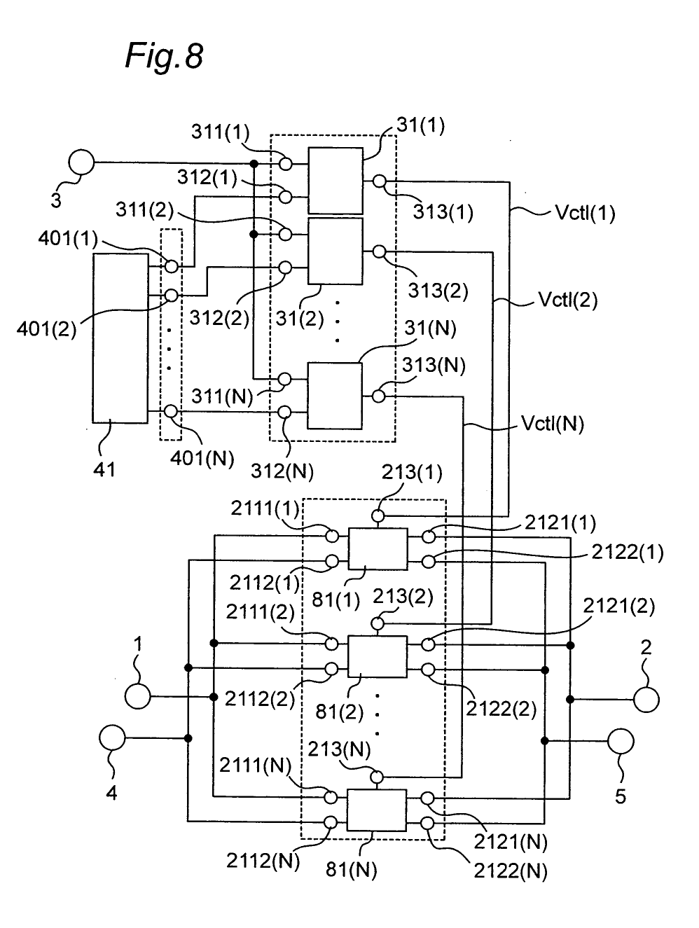

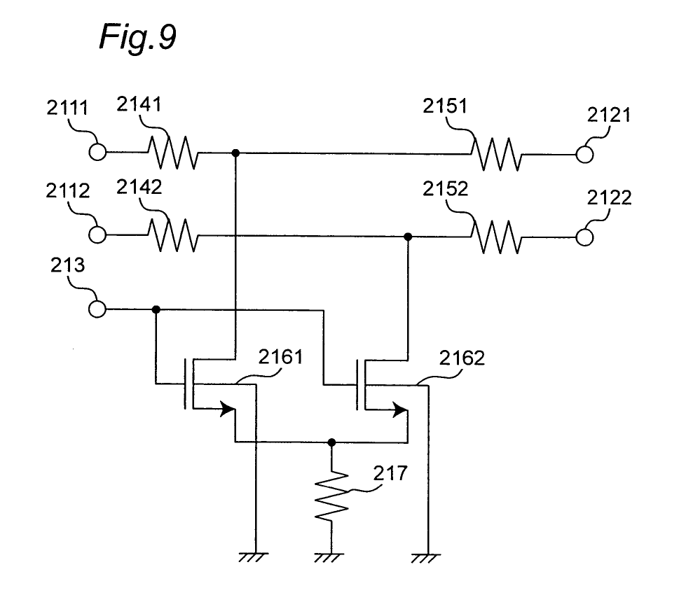

A variable attenuator according to a second embodiment will be described with reference to FIGS. 8 and 9. FIG. 8 shows the variable attenuator according to the second embodiment of the present invention. In FIG. 8, the same reference numerals indicate the same elements as those shown in FIG. 1.

The variable attenuator in the second embodiment is different from that in the first embodiment in respect to have a pair of signal input terminals 1 and 4 receiving a signal of which attenuation is controlled, a pair of signal output terminals 2 and 5 outputting an attenuated signal and a variable impedance element 81(i) (1≦i≦N).

Since the other configuration (the analog/digital converter and the like) is the same as that in the first embodiment, their detailed descriptions will be omitted. The variable impedance element according to the second embodiment will be described.

The variable impedance elements 81(1) to 81(N) have the same circuit configuration and the same circuit constant. Each of the variable impedance elements 81(1) to 81(N) has a first circuit connected in parallel between the signal input terminal 1 and the signal output terminal 2, and a second circuit connected in parallel between the signal input terminal 4 and the signal output terminal 5. The first and second circuits have substantially the same circuit configuration and the same circuit constant. The variable impedance element 81(i) (1≦i≦N) receives a control signal Vctl(i) and is switched to either of two impedance values.

FIG. 9 shows a configuration of the variable impedance element 81(i) in the second embodiment. The variable impedance element 81(i) (1≦i≦N) has signal input terminals 2111 and 2112, signal output terminals 2121 and 2122, a control terminal 213 for receiving the control signal, resistors 2141, 2151, 2142, 2152 and 217, and N-type MOS transistors 2161 and 2162.

The first circuit has the signal input terminal 2111, the signal output terminal 2121, the control terminal 213, the resistors 2141, 2151 and 217, and the N-type MOS transistor 2161. The second circuit has the signal input terminal 2112, the signal output terminal 2122, the control terminal 213 for receiving the control signal, the resistors 2142, 2152 and 217, and the N-type MOS transistor 2162. The first and second circuits share the control terminal 213 and the resistor 217.

A resistance value R2141 of the resistor 2141, a resistance value R2151 of the resistor 2151, a resistance value R2142 of the resistor 2142, and a resistance value R2152 of the resistor 2152 are the same value R.

The N-type MOS transistor 2161 is a switching element that has a drain connected to a connecting point between the resistor 2141 and the resistor 2151, a source grounded through the resistor 217 and a gate, and that is turned on or off based on the control signal Vct1(i) (1≦i≦N) which is inputted to the gate.

The transistor 2162 is a switching element that has a drain connected to a connecting point between the resistor 2142 and the resistor 2152, a source grounded through the resistor 217 and a gate, and that is turned on or off based on the control signal Vct1(i) (1≦i≦N) which is inputted to the gate.

As shown in FIG. 2, according to the variable impedance element of the first embodiment, the source of the MOS transistor 216 is grounded. In this case, parasitic impedance between the source and ground affects attenuation characteristics largely. In addition, a noise from the ground affects the signal in some cases.

According to the variable impedance element 81(i) in the second embodiment, the resistor 217 is provided between the source and the ground of each of the two N-type MOS transistors 2161 and 2162 to prevent the attenuation characteristics from being affected by a parasitic impedance between the source and ground.

The variable attenuator according to the second embodiment receives two balanced input signals (differential signal pair) or two complemented input signals and outputs attenuated signals. Thus, the signal can be prevented from being affected by a noise from the ground.

### EMBODIMENT 3

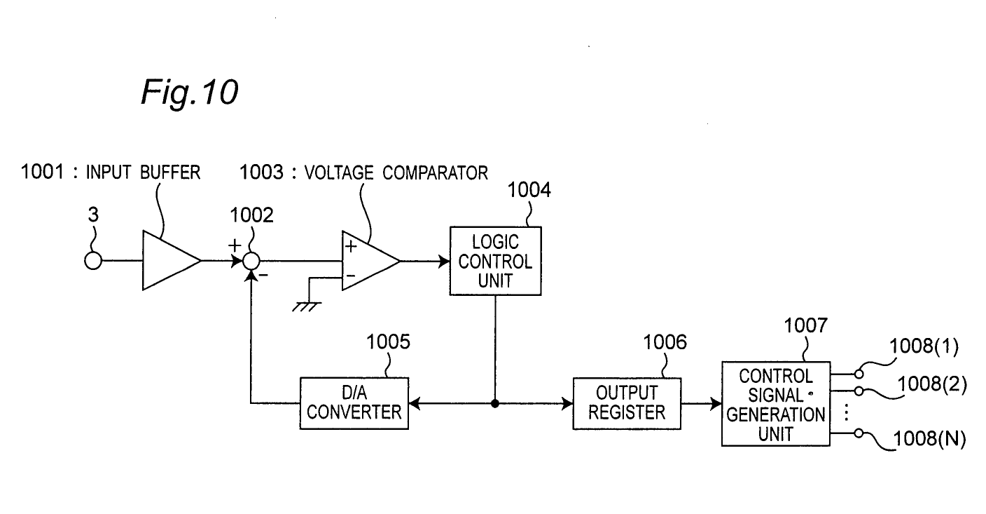

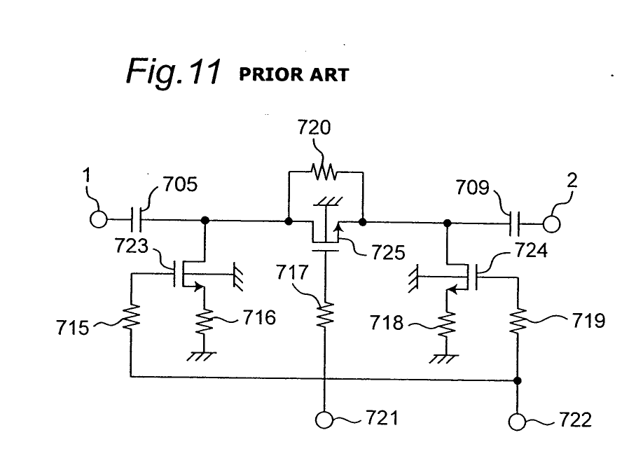

A variable attenuator according to a third embodiment of the present invention will be described with reference to FIG. 10. The variable attenuator according to the third embodiment has an analog/digital converter which is different from that in the first embodiment. The other configuration of the variable attenuator according to the third embodiment is the same as that in the first embodiment. A configuration of the analog/digital converter of the variable attenuator according to the third embodiment will be described.

FIG. 10 is a block diagram showing the configuration of the analog/digital converter in the third embodiment. The analog/digital converter in the third embodiment has a configuration shown in FIG. 10 instead of the reference voltage source 41 and the voltage comparator 31 in the first embodiment.

Referring to FIG. 10, the analog/digital converter is a sequentially comparative type which has an input buffer 1001 connected to a control terminal 3, a subtracter 1002 subtracting an output of a D/A converter 1005 from an output of the input buffer 1001, a voltage comparator 1003 having non-inverting input terminal connected to an output of the subtracter 1002, a logic control unit 1004 connected to an output terminal of the voltage comparator 1003, the p-bit(p is a positive integer of 2 or more) digital/analog converter 1005 receiving an output of the logic control unit 1004, an output register 1006 connected to the logic control unit 1004, a control signal generation unit 1007 connected to the output register 1006, and N control signal output terminals 1008(1) to 1008(N) connected to the control signal generation unit 1007.

In the third embodiment, a description will be made assuming that the bit number p of the D/A converter 1005 is such that p=4.

The input buffer 1001 receives a control voltage. The logic control unit 1004 sets 1000B (B designates the binary number) to the D/A converter 1005 first. The subtracter 1002 subtracts the voltage(corresponding to the digital value 1000B) outputted from the D/A converter 1005, from the control voltage outputted from the input buffer 1001, and outputs its subtracted result.

The voltage comparator 1003 receives the subtracted result and outputs a High-level output signal when the result is a positive value and outputs a Low-level output signal when the result is a negative value. When the output level of the voltage comparator 1003 is High level, the logic control unit 1004 sets the MSB to 1 and when the output level of the voltage comparator 1003 is Low level, it sets the MSB to 0.

For example, when the MSB is 0, the logic control unit 1004 sets 0100B to the D/A converter 1005. The subtracter 1002 subtracts the voltage(corresponding to the digital value 0100B) outputted from the D/A converter 1005, from the control voltage outputted from the input buffer 1001, and outputs its subtracted result.

The voltage comparator 1003 receives the subtracted result and outputs the High-level output signal when the result is the positive value and outputs the Low-level output signal when the result is the negative value. When the output level of the voltage comparator 1003 is the High level, the logic control unit 1004 sets the upper second bit to 1 and when the output level of the voltage comparator 1003 is the Low level, it sets the upper second bit to 0.

Similarly, the above operation is repeated to determine the p-bit(4-bit) digital value.

Then, the logic control unit 1004 loads the 4-bit digital value to the output register 1006. The output register 1006 holds the value until the logic control unit 1004 loads a new 4-bit digital value.

The control signal generation unit 1007 is a decoder. The control signal generation unit 1007 receives a counter value K outputted from the output register 1006 and outputs the Low-level control signals from the control signal output terminals 1008(1) to 1008(K) of which number is the same as the counter value K and outputs the High-level control signals from the(N−K) control signal output terminals 1008(K+1) to 1008(N). The control signal output terminal 1008(i) (1≦i≦N) is connected to the control terminal 213(i) of the variable impedance element 21(i).

Similarly, the above processes are repeated.

According to the above configuration, the analog/digital converter in the third embodiment outputs K (K is an integer satisfying 0≦k≦N) Low-level control signals of which number is almost proportional to a level of the control voltage, and(N−K) High-level control signals.

According to the third embodiment, the plurality of voltage comparators 1003 may be provided and the plural bits of the digital value may be decided at a time.

A reference voltage retention unit may be provided instead of the D/A converter 1005. The reference voltage retention unit has a capacitor keeping a reference voltage, a charging circuit which charges the capacitor with a voltage corresponding to the 1LSB, a discharging circuit which discharges the voltage corresponding to the lLSB from the capacitor, and an output buffer which outputs the voltage retained by the capacitor.

With respect to the digital value of the last digital/analog converted result as the stating point, the logic control unit 1004 increments the digital value and sends a charging instruction to the charging circuit, and decrements the digital value and sends a discharging instruction to the discharging circuit.

When the output value of the voltage comparator 1003 is changed from the High level to the Low level, or changed from the Low level to the High level, the digital value kept by the logic control unit 1004 becomes the digital/analog converted result.

According to the embodiments 1 to 3, the N variable impedance elements are connected in parallel between the signal input terminal and the signal output terminal. Instead, the N variable impedance element may be connected in series between the signal input terminal and the signal output terminal.

As still another configuration, N2 (N2 is a positive integer of 2 or more) serial units which have N1 (N1 is a positive integer of 2 or more) variable impedance elements connected in series may be connected in parallel between the signal input terminal and the signal output terminal.

Furthermore, there may be such configuration that the analog/digital converter converts the control voltage to M (M is a positive integer satisfying 2≦M<N) control signals and the plurality of variable impedance elements receive the same control signal.

In addition, characteristics of the signal attenuation may be adjusted by differentiating the circuit configurations and the circuit constants of the N variable impedance elements and the N voltage comparators from each other.

However, a variable attenuator having the above configuration has signal attenuation characteristics different from those of the variable attenuator in the above embodiment. Preferably, it has the same configuration as that in the above embodiment.

Although the present invention has been described with respect to its preferred embodiments in some detail, the disclosed contents of the preferred embodiments may change in the details of the structure thereof, and any changes in the combination and sequence of the component may be attained without departing from the scope and spirit of the claimed invention.

### INDUSTRIAL APPLICABILITY

The present invention can be advantageously applied to a variable attenuator and a semiconductor device using it.

1. A variable attenuator comprising:
a first signal input terminal;
a first signal output terminal;
a first control terminal receiving a control voltage;
an analog/digital converter converting the control voltage to M (M is a positive integer of 2 or more) control signals; and
N (N is a positive integer satisfying N≧M) variable impedance elements which are connected in parallel and/or in series between the first signal input terminal and the first signal output terminal, each impedance of which being varied by either one of the control signals.

2. The variable attenuator according to claim 1, wherein the N variable impedance elements have the same configuration and are connected in parallel between the first signal input terminal and the first signal output terminal.

3. The variable attenuator according to claim 1, wherein
the control signals are binary digital signals having a first value and a second value, and the analog/digital converter outputs K (K is an integer satisfying 0≦K≦M) control signals having the first value and (M−K) control signals having the second value, a number of K being almost in proportion to a level of the control voltage, and
N and M are the same value, and the N variable impedance elements have the same configuration and are connected in parallel between the first signal input terminal and the first signal output terminal and switched to have either one of two impedance values by the respective control signals.

4. The variable attenuator according to claim 3, wherein
the variable impedance element comprises:
a second signal input terminal;
a second signal output terminal;
a second control terminal receiving a control signal;
a constant voltage terminal;
a series connector having two resistors which are connected in series and have almost the same impedance, and being inserted between the second signal input terminal and the second signal output terminal; and
a switching element which is inserted between a connecting point of the two resistors and the constant voltage terminal and is turned on or off by the control signal.

5. The variable attenuator according to claim 1, wherein
the variable impedance element comprises:
a second signal input terminal;
a second signal output terminal;
a second control terminal receiving a control signal;
a constant voltage terminal;
a series connector having first and second passive elements connected in series, and being inserted between the second signal input terminal and the second signal output terminal; and
a first MOS transistor which has a drain connected to a connecting point between the first and second passive elements, a source connected to the constant voltage terminal directly or through a resistor, and a gate receiving the control signal.

6. The variable attenuator according to claim 5, wherein the first and second passive elements are resistors.

7. The variable attenuator according to claim 1, further comprising a third signal input terminal and a third signal output terminal, wherein
each variable impedance element further comprises a second circuit which is the same circuit as a first circuit connected between the first signal input terminal and the first signal output terminal in parallel or in series, and impedance of which is varied by the same control signal, and
the second circuits of the N variable impedance elements are connected in parallel or in series between the third signal input terminal and the third signal output terminal.

8. The variable attenuator according to claim 7, wherein
the variable impedance element comprises:
a second signal input terminal;
a second signal output terminal;
a fourth signal input terminal;
a fourth signal output terminal;
a second control terminal receiving the control signal;
a constant voltage terminal;
a first series connector having first and second passive elements which are connected in series and inserted between the second signal input terminal and the second signal output terminal;
a second series connector having third and fourth passive elements which are connected in series and inserted between the fourth signal input terminal and the fourth signal output terminal;
a first MOS transistor which has a drain connected to a connecting point between the first and second passive elements, a source connected to the constant voltage terminal directly or through a fifth passive element and a gate receiving the control signal; and
a second MOS transistor which has a drain connected to a connecting point between the third and fourth passive elements, a source connected to the constant voltage terminal directly or through the fifth passive element, or through a sixth passive element having the same impedance as that of the fifth passive element and a gate receiving the control signal.

9. The variable attenuator according to claim 8, wherein the first, second, third, and fourth passive elements are resistors, or those passive element and the fifth passive element are resistors, or those passive elements and the fifth and sixth passive elements are resistors.
